(19) United States
(12) Patent Application Publication
(10) Pub. No.: US 2025/0378856 A1
(43) Pub. Date: Dec. 11, 2025

(54) SEMICONDUCTOR DEVICE

(71) Applicant: SAMSUNG ELECTRONICS CO., LTD., Suwon-si (KR)

(72) Inventors: Jee Woong KIM, Suwon-si (KR); Jin Kyu KIM, Suwon-si (KR); Yun Suk NAM, Suwon-si (KR); Kyo-Wook LEE, Suwon-si (KR)

(73) Assignee: SAMSUNG ELECTRONICS CO., LTD., Suwon-si (KR)

(21) Appl. No.: 19/071,032

(22) Filed: Mar. 5, 2025

(30) Foreign Application Priority Data
Jun. 5, 2024 (KR) 10-2024-0073689

(51) Int. Cl. G11C 5/06; G11C 11/413; H10B 10/00; H10D 30/00; H10D 30/43; H10D 64/23

(52) U.S. Cl. CPC G11C 5/063; G11C 11/413; H10B 10/12; H10D 30/43; H10D 30/502; H10D 64/251

(57) ABSTRACT

A semiconductor device includes: a substrate having first and second surfaces; a wordline including a front wiring pattern on the first surface and a back wiring pattern on the second surface; a bitline and a complementary bitline on the substrate; and first and second cells on the substrate. The first cell includes: a latch circuit with first and second inverters; a first pass transistor connected between an output node of the first inverter and the bitline; and a second pass transistor connected between an output node of the second inverter and the complementary bitline. The second cell includes a through via penetrating the substrate and connecting the front wiring pattern and the back wiring pattern.

### CROSS-REFERENCE TO RELATED APPLICATION

This application claims priority from Korean Patent Application No. 10-2024-0073689, filed on Jun. 5, 2024, in the Korean Intellectual Property Office, the disclosure of which is hereby incorporated by reference in its entirety.

### BACKGROUND

### 1. Field

The present disclosure relates to a semiconductor device, and more particularly, to a semiconductor device including a Backside Power Delivery Network (BSPDN).

### 2. Description of Related Art

Due to characteristics such as miniaturization and multifunctionality, semiconductor devices have been spotlighted as important elements in the electronics industry. Semiconductor devices can be categorized into semiconductor memory devices that store logical data, semiconductor logic devices that process logical data, and hybrid semiconductor devices that include both memory elements and logic elements.

As the electronics industry has advanced significantly, the demand for improved characteristics of semiconductor devices has been steadily increasing. For example, there is a growing demand for high reliability, high speed, and/or multifunctionality in semiconductor devices. To meet these characteristics, the structures within semiconductor devices are becoming increasingly complex and highly integrated.

### SUMMARY

One or more embodiments provide a semiconductor device with enhanced performance.

Aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of an embodiment, a semiconductor device includes: a substrate having first and second surfaces that are opposite to each other; a wordline including a front wiring pattern on the first surface, extending in a first direction, and a back wiring pattern on the second surface, extending in the first direction; a bitline and a complementary bitline on the substrate, extending in parallel to each other in a second direction intersecting the first direction; and first and second cells on the substrate, arranged along the first direction. The first cell includes: a latch circuit including a first inverter and a second inverter; a first pass transistor connected between an output node of the first inverter and the bitline; and a second pass transistor connected between an output node of the second inverter and the complementary bitline. The wordline is connected to a gate of the first pass transistor and a gate of the second pass transistor. The second cell includes a through via penetrating the substrate and connecting the front wiring pattern and the back wiring pattern.

According to another aspect of an embodiment, a semiconductor device includes: a substrate having first and second surfaces that are opposite to each other; a cell array region on the substrate, the cell array region including a plurality of memory cells arranged in a matrix form along a first direction and a second direction that intersects the first direction; a wordline commonly connected to a row of memory cells extending in the first direction, among the plurality of memory cells; a bitline commonly connected to a column of memory cells extending in the second direction, among the plurality of memory cells; and a transfer cell region extending in the first direction. The wordline includes a front wiring pattern on the first surface, extending in the first direction, and a back wiring pattern on the second surface, extending in the first direction. The transfer cell region includes a through via penetrating the substrate to connect the front wiring pattern and the back wiring pattern.

According to still another aspect of an embodiment, a semiconductor device includes: a first cell and a second cell arranged along a first direction; a substrate having a first and second surface that are opposite to each other; first through fourth active patterns on the first surface of the substrate, sequentially arranged along the first direction and extending in a second direction intersecting the first direction; a first gate structure extending in the first direction and intersecting the first active pattern; a second gate structure extending in the first direction and intersecting the third active pattern and the fourth active pattern; a third gate structure extending in the first direction and intersecting the first active pattern and the second active pattern; a fourth gate structure extending in the first direction and intersecting the fourth active pattern; a first source/drain contact connecting the first active pattern and the second active pattern, the first source/drain contact extending between the first gate structure and the third gate structure, and between the second gate structure and the third gate structure; a second source/drain contact connecting the third active pattern and the fourth active pattern, the second source/drain contact extending between the second gate structure and the fourth gate structure, and between the second gate structure and the third gate structure; a first shared contact connecting the second gate structure and the first source/drain contact; a second shared contact connecting the third gate structure and the second source/drain contact; a first front wiring pattern on the first surface, extending in the first direction and connected to the first gate structure and the fourth gate structure; a first back wiring pattern on the second surface, extending in the first direction; and a through via in the second cell, penetrating the substrate and connecting the first front wiring pattern and the first back wiring pattern.

It should be noted that the effects of the present disclosure are not limited to those described above, and other effects of the present disclosure will be apparent from the following description.

### BRIEF DESCRIPTION OF DRAWINGS

The above and other aspects and features will be more apparent from the following description of embodiments, taken in conjunction with the accompanying drawings, in which:

FIG. 1 is a block diagram for explaining a semiconductor device according to some embodiments.

FIG. 2 is a circuit diagram for explaining a unit memory cell of the semiconductor device according to some embodiments.

FIG. 3 is a layout view for explaining a unit memory cell of the semiconductor device according to some embodiments.

FIG. 4 is a schematic cross-sectional view taken along line A-A of FIG. 3.

FIG. 5 is a schematic cross-sectional view taken along line B-B of FIG. 3.

FIG. 6 is a schematic cross-sectional view taken along line C-C of FIG. 3.

FIG. 7 is a schematic cross-sectional view taken along line D-D of FIG. 3.

FIG. 8 is a layout view for explaining a unit transfer cell of the semiconductor device according to some embodiments.

FIG. 9 is a schematic cross-sectional view taken along line E-E of FIG. 8.

FIG. 10 is a schematic cross-sectional view for explaining a unit transfer cell of a semiconductor device according to some embodiments.

FIG. 11 is a layout view for explaining a unit memory cell of a semiconductor device according to some embodiments.

FIG. 12 is a schematic cross-sectional view for explaining a unit transfer cell of a semiconductor device according to some embodiments.

FIG. 13 is a schematic cross-sectional view taken along line F-F of FIG. 12.

FIGS. 14 and 15 are block diagrams for explaining semiconductor devices according to some embodiments.

FIG. 16 is a circuit diagram for explaining a semiconductor device according to some embodiments.

FIGS. 17 and 18 are exemplary layout views for explaining the semiconductor device of FIG. 16.

### DETAILED DESCRIPTION

Hereinafter, embodiments are described in detail with reference to the accompanying drawings. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each embodiment provided in the following description is not excluded from being associated with one or more features of another example or another embodiment also provided herein or not provided herein but consistent with the present disclosure. In this specification, although terms like “first,” “second,” etc., are used to describe various elements or components, these elements or components are not limited by these terms. These terms are merely used to distinguish one element or component from another. Therefore, a first element or component mentioned below may be a second element or component without departing from the technical scope of the present disclosure.

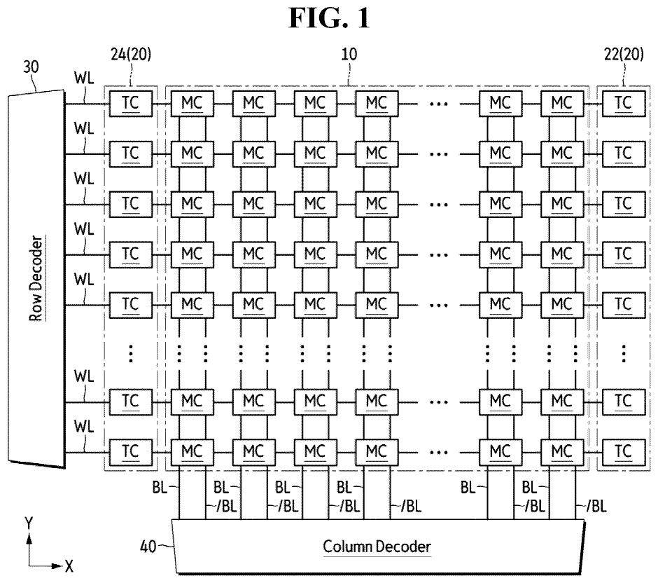

A semiconductor device according to some embodiments will hereinafter be described with reference to FIGS. 1 through 18. The description primarily describes a Static Random Access Memory (SRAM) device as an exemplary semiconductor device, but embodiments are not limited thereto. Those skilled in the art will understand that the technical concept can be applied not only to SRAM devices but also to various other semiconductor devices, including logic devices.

FIG. 1 is a block diagram for explaining a semiconductor device according to some embodiments.

Referring to FIG. 1, the semiconductor device according to some embodiments includes a cell array region 10, transfer cell regions 20, a row decoder (i.e., row decoder circuit) 30, and a column decoder (i.e., column decoder circuit) 40.

The cell array region 10 may include a plurality of memory cells MC that are arranged in a two-dimensional (2D) array. For example, the memory cells MC may be arranged in a matrix form along a first direction X and a second direction Y that intersect each other. In this specification, the memory cells MC may also be referred to as first cells.

The cell array region 10 may be connected to the row decoder 30 through a plurality of wordlines WL. The wordlines WL may be spaced apart from one another and extend in parallel in the first direction X. Each of the wordlines WL may extend in the first direction X to be commonly connected to a single row of memory cells MC arranged in the first direction X.

The cell array region 10 may be connected to the column decoder 40 through a plurality of bitlines BL and a plurality of complementary bitlines/BL. The bitlines BL and the complementary bitlines/BL may be spaced apart from each other and may extend in parallel to each other in the second direction Y. Each pair of one bitline BL and one complementary bitline/BL that are adjacent to each other may extend in the second direction Y to be commonly connected to a single column of memory cells MC arranged in the second direction Y.

The row decoder 30 may select at least one of the wordlines WL. Additionally, the row decoder 30 may transfer a voltage for performing a memory operation on the selected wordline WL. The row decoder 30 may include, for example, a wordline decoder and/or a wordline driver, but the present disclosure is not limited thereto.

The column decoder 40 may select at least one pair of bitline BL and complementary bitline/BL. Additionally, the column decoder 40 may transfer a voltage for performing a memory operation on the selected pair of bitline BL and complementary bitline/BL. The column decoder 40 may include, for example, a bitline multiplexer and/or a sense amplifier, but the present disclosure is not limited thereto.

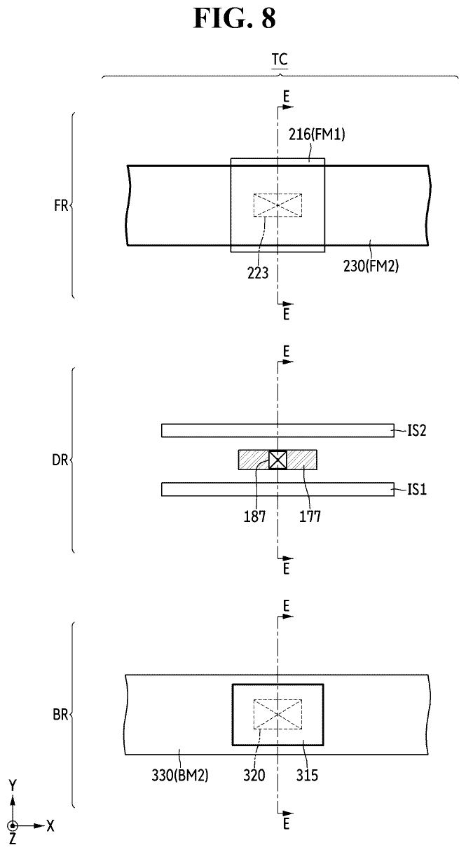

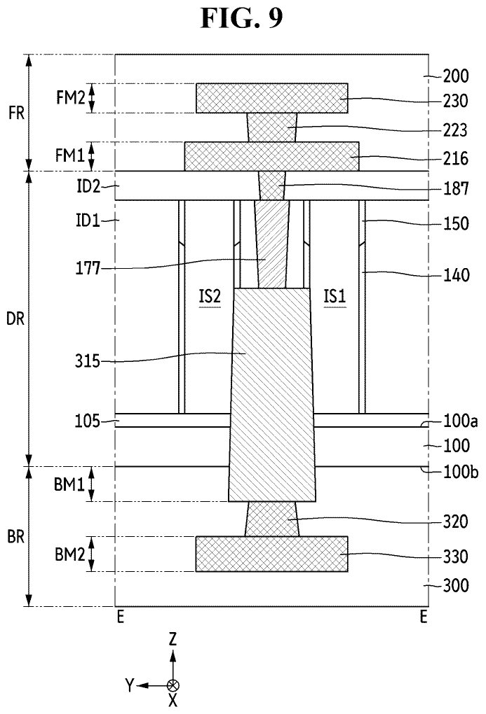

The transfer cell regions 20 may be arranged along the first direction X with the cell array region 10. Each of the transfer cell regions 20 may include a plurality of transfer cells TC. The transfer cells TC may be arranged along the first direction X with the respective rows of memory cells MC. The wordlines WL may extend in the first direction X to be commonly connected to the respective rows of memory cells MC and the respective transfer cells TC. The transfer cells TC will be described later in further detail with reference to FIGS. 8 and 9. In this specification, the transfer cells TC may also be referred to as second cells.

In some embodiments, the transfer cell regions 20 may be disposed on at least one side of the cell array region 10 in the first direction X. For example, the transfer cell regions 20 may include a first transfer cell region 22 and a second transfer cell region 24, which are disposed on either side of the cell array region 10 in the first direction X. The cell array region 10 may be interposed between the first transfer cell region 22 and the row decoder 30 in the first direction X. The second transfer cell region 24 may be interposed between the cell array region 10 and the row decoder 30 in the first direction X. Each of the first and second transfer cell regions 22 and 24 may include a plurality of transfer cells TC that are arranged along the second direction Y.

In some embodiments, one of the first and second transfer cell regions 22 and 24 may be omitted.

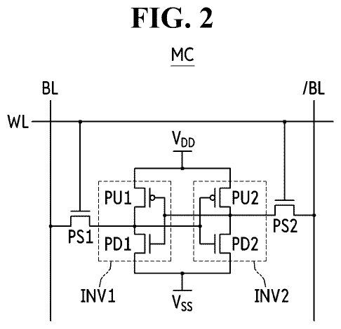

FIG. 2 is a circuit diagram for explaining a unit memory cell of the semiconductor device according to some embodiments.

Referring to FIG. 2, a memory cell MC of the semiconductor device according to some embodiments includes a pair of first and second inverters INV1 and INV2, which are connected in parallel between a power supply node V_{DD} and a ground node V_{SS}, and a first pass transistor PS1 and a second pass transistor PS2, which are connected to the output nodes of the inverters INV1 and INV2, respectively.

To form a latch circuit, the input node of the first inverter INV1 may be connected to the output node of the second inverter INV2, and the input node of the second inverter INV2 may be connected to the output node of the first inverter INV1.

The first inverter INV1 may include a first pull-up transistor PU1 and a first pull-down transistor PD1, which are connected in series, and the second inverter INV2 may include a second pull-up transistor PU2 and a second pull-down transistor PD2, which are connected in series. The first and second pull-up transistors PU1 and PU2 may be P-type Field Effect Transistor (PFETs), and the first and second pull-down transistors PD1 and PD2 may be N-type Field Effect Transistors (NFETs).

The first pass transistor PS1 may connect a bitline BL to the output node of the first inverter INV1. The second pass transistor PS2 may connect a complementary bitline/BL to the output node of the second inverter INV2. The gates of the first and second pass transistors PS1 and PS2 may both be connected to a wordline WL.

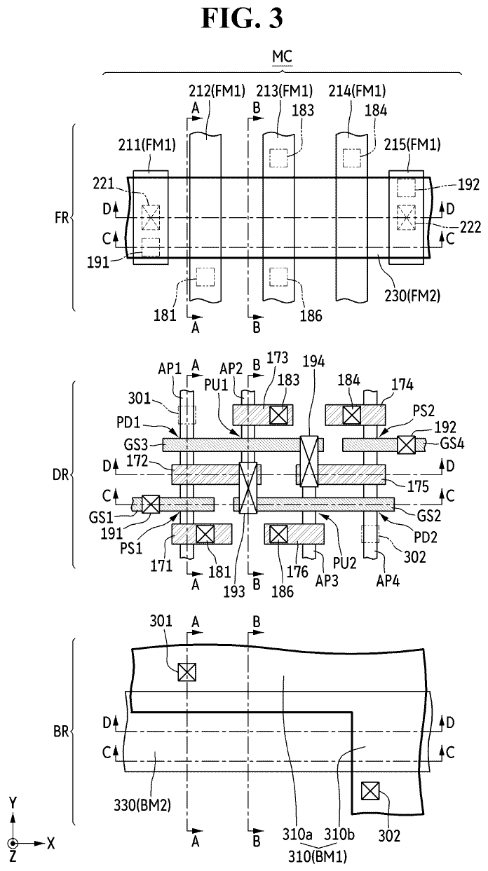

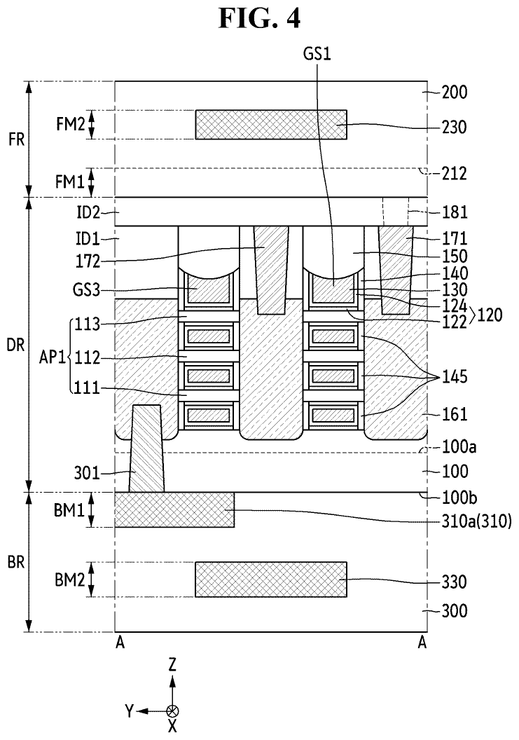

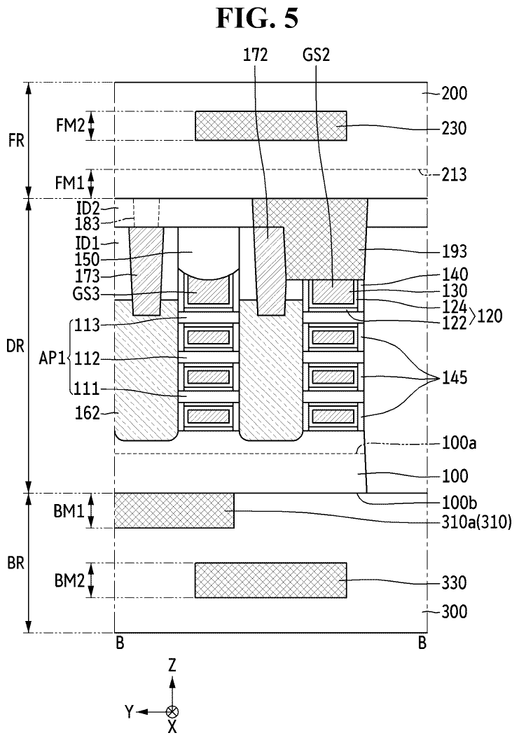

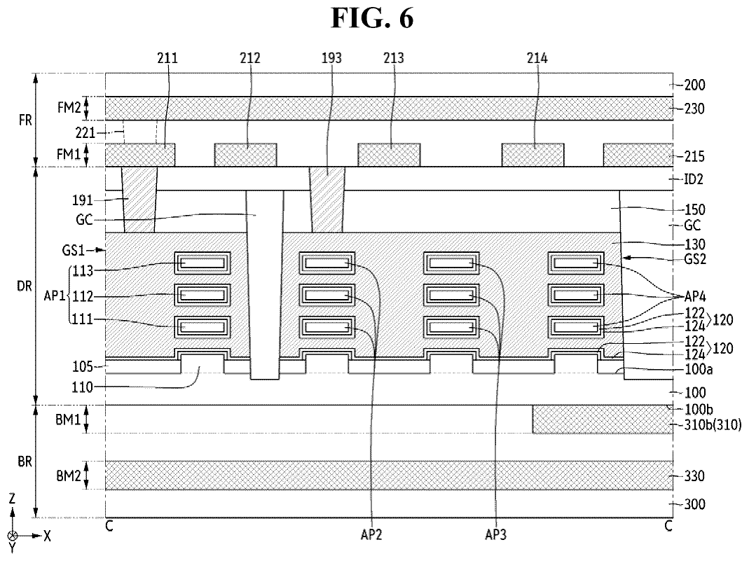

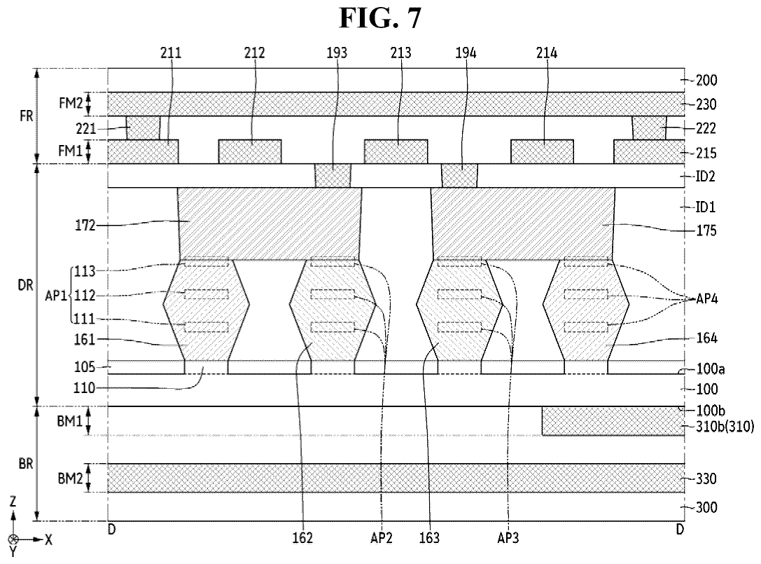

FIG. 3 is a layout view for explaining a unit memory cell of the semiconductor device according to some embodiments. FIG. 4 is a schematic cross-sectional view taken along line A-A of FIG. 3. FIG. 5 is a schematic cross-sectional view taken along line B-B of FIG. 3. FIG. 6 is a schematic cross-sectional view taken along line C-C of FIG. 3. FIG. 7 is a schematic cross-sectional view taken along line D-D of FIG. 3. FIG. 8 is a layout view for explaining a unit transfer cell of the semiconductor device according to some embodiments. FIG. 9 is a schematic cross-sectional view taken along line E-E of FIG. 8.

Referring to FIGS. 1 through 9, the semiconductor device according to some embodiments includes a device region DR, a front region FR, and a back region BR.

The device region DR may include a substrate 100, a field insulating film 105, first through fourth active patterns AP1 through AP4, first through fourth gate structures GS1 through GS4, first through sixth source/drain contacts 171 through 176, a first interlayer insulating film ID1, and a second interlayer insulating film ID2.

The substrate 100 may include bulk silicon (Si) or Si-on-insulator (SOI). Alternatively, the substrate 100 may be a Si substrate or may include other materials, for example, silicon-germanium (SiGe), SiGe-on-insulator (SGOI), indium antimonide, a lead telluride compound, indium arsenide, indium phosphide, gallium arsenide, or gallium antimonide. Alternatively, the substrate 100 may have an epitaxial layer formed on a base substrate.

In some embodiments, the substrate 100 may be an insulating substrate containing an insulating material. For example, the substrate 100 may include at least one of silicon oxide, silicon oxynitride, silicon oxynitride, and a combination thereof, but the present disclosure is not limited thereto. For example, the substrate 100 may include a silicon oxide film.

The substrate 100 may include first and second surfaces 100a and 100b that are opposite to each other. The first surface 100a may also be referred to as the front side of the substrate 100, and the second surface 100b may also be referred to as the back side of the substrate 100.

The first through fourth active patterns AP1 through AP4 may be formed on the first surface 100a of a memory cell MC. The first through fourth active patterns AP1 through AP4 may be sequentially arranged along the first direction X. The first through fourth active patterns AP1 through AP4 may be spaced apart from one another in the first direction X and may extend longitudinally in the second direction Y.

Each of the first through fourth active patterns AP1 through AP4 may include an elemental semiconductor material such as Si or germanium (Ge). Alternatively, each of the first through fourth active patterns AP1 through AP4 may include a compound semiconductor such as a Group IV-IV compound semiconductor or a Group III-V compound semiconductor. The Group IV-IV compound semiconductor may include a binary compound or ternary compound containing at least two of carbon (C), Si, Ge, and tin (Sn), or a compound obtained by doping the binary or ternary compound with a Group IV element. The Group III-V compound semiconductor may include a binary, ternary, or quaternary compound obtained by combining at least one Group III element such as aluminum (Al), gallium (Ga), or indium (In) with at least one Group V element such as phosphorus (P), arsenic (As), or antimony (Sb).

In some embodiments, the first and fourth active patterns AP1 and AP4 may be used as channel regions for NFETs, and the second and third active patterns AP2 and AP3 may be used as channel regions for PFETs.

In some embodiments, the first through fourth active patterns AP1 through AP4 may each include a plurality of bridge patterns (e.g., first through third bridge patterns 111 through 113) that are sequentially stacked on the substrate 100 and spaced apart from one another. The first through fourth active patterns AP1 through AP4 may be used as channel regions of Multi-Bridge Channel Field-Effect Transistors (MBCFETs®) that include multi-bridge channels. The number of bridge patterns included in each of the first through fourth active patterns AP1 through AP4 is not particularly limited and may vary.

In some embodiments, fin patterns 110 may be formed between the substrate 100 and the first bridge patterns 111. The fin patterns 110 may protrude from the first surface 100a of the substrate 100 and extend in the second direction Y. In some embodiments, the fin patterns 110 may be insulating patterns that include an insulating material.

The field insulating film 105 may be formed on the substrate 100. In some embodiments, the field insulating film 105 may cover at least parts of the side surfaces of the fin patterns 110. The field insulating film 105 may include, for example, at least one of silicon oxide, silicon nitride, silicon oxynitride, and a combination thereof, but the present disclosure is not limited thereto.

The first through fourth gate structures GS1 through GS4 may be formed on the substrate 100 and the field insulating film 105. Each of the first through fourth gate structures GS1 through GS4 may extend longitudinally in the first direction X.

The first gate structure GS1 may intersect the first active pattern AP1. For example, the first through third bridge patterns 111 through 113 of the first active pattern AP1 may extend in the second direction Y and penetrate the first gate structure GS1. The first gate structure GS1 may serve as the gate of the first pass transistor PS1. For example, the first active pattern AP1 intersecting the first gate structure GS1 may serve as the channel region of the first pass transistor PS1.

The second gate structure GS2 may be spaced apart from the first gate structure GS1 in the first direction X. The second gate structure GS2 may intersect the third and fourth active patterns AP3 and AP4. For example, the first through third bridge patterns 111 through 113 of the third active pattern AP3 and the first through third bridge patterns 111 through 113 of the fourth active pattern AP4 may extend in the second direction Y and penetrate the second gate structure GS2. The second gate structure GS2 may serve as the gate of the second inverter INV2. For example, the third active pattern AP3 intersecting the second gate structure GS2 may serve as the channel region of the second pull-up transistor PU2, and the fourth active pattern AP4 intersecting the second gate structure GS2 may serve as the channel region of the second pull-down transistor PD2.

The third gate structure GS3 may be spaced apart from the first and second gate structures GS1 and GS2 in the second direction Y. The third gate structure GS3 may intersect the first and second active patterns AP1 and AP2. For example, the first through third bridge patterns 111 through 113 of the first active pattern AP1 and the first through third bridge patterns 111 through 113 of the second active pattern AP2 may extend in the second direction Y and penetrate the third gate structure GS3. The third gate structure GS3 may serve as the gate of the first inverter INV1. For example, the first active pattern AP1 intersecting the third gate structure GS3 may serve as the channel region of the first pull-down transistor PD1, and the second active pattern AP2 intersecting the third gate structure GS3 may serve as the channel region of the first pull-up transistor PU1.

The fourth gate structure GS4 may be spaced apart from the third gate structure GS3 in the first direction X. The fourth gate structure GS4 may intersect the fourth active pattern AP4. For example, the first through third bridge patterns 111 through 113 of the fourth active pattern AP4 may extend in the second direction Y and penetrate the fourth gate structure GS4. The fourth gate structure GS4 may serve as the gate of the second pass transistor PS2. For example, the fourth active pattern AP4 intersecting the fourth gate structure GS4 may serve as the channel region of the second pass transistor PS2.

In some embodiments, the first through fourth gate structures GS1 through GS4 may be separated by separation patterns GC. For example, the separation patterns GC may extend in the second direction Y between the first active pattern AP1 and the second active pattern AP2, thereby separating the first and second gate structures GS1 and GS2. Additionally, for example, the separation patterns GC may extend in the second direction Y between the third and fourth active patterns AP3 and AP4, thereby separating the third and fourth gate structures GS3 and GS4.

The separation patterns GC may include an insulating material, for example, at least one of silicon oxide, silicon nitride, silicon oxynitride, silicon oxycarbide, silicon nitride boron, silicon carbonitride boron, silicon oxycarbonitride, and a combination thereof, but the present disclosure is not limited thereto.

In some embodiments, each of the first through fourth gate structures GS1 through GS4 may include a gate dielectric film 120, a gate electrode 130, gate spacers 140, and a gate capping film 150.

The gate dielectric film 120 may be interposed between the gate electrode 130 and each of the first through fourth active patterns AP1 through AP4. The gate dielectric film 120 may include a dielectric material, for example, at least one of silicon oxide, silicon oxynitride, silicon nitride, and a high-k dielectric material with a greater dielectric constant than silicon oxide.

The gate electrode 130 may extend longitudinally in the first direction X and intersect each of the first through fourth active patterns AP1 through AP4. The first through third bridge patterns 111 through 113 of each of the first through fourth active patterns AP1 through AP4 may extend in the second direction Y and penetrate the gate electrode 130. The gate electrode 130 may include a conductive material, for example, at least one of TiN, WN, TaN, Ru, TiC, TaC, Ti, Ag, Al, TiAl, TiAlN, TiAlC, TaCN, TaSiN, Mn, Zr, W, Al, and a combination thereof, but the present disclosure is not limited thereto. The gate electrode 130 may be formed by a replacement process, but the present disclosure is not limited thereto.

The gate electrode 130 is illustrated as being a single layer, but the present disclosure is not limited thereto. Alternatively, the gate electrode 130 may be a multilayer structure where a plurality of conductive films are stacked. For example, the gate electrode 130 may include a work function tuning layer and a filling conductive layer that fills the space formed by the work function tuning layer. The work function tuning layer may include, for example, at least one of TiN, TaN, TiC, TaC, TiAlC, and a combination thereof. The filling conductive layer may include, for example, W or Al.

The gate spacers 140 may extend along the side surfaces of the gate electrode 130. The first through third bridge patterns 111 through 113 of each of the first through fourth active patterns AP1 through AP4 may extend in the second direction Y and penetrate the gate spacers 140. The gate spacers 140 may include an insulating material, for example, at least one of silicon oxide, silicon nitride, silicon oxynitride, silicon oxycarbide, silicon nitride boron, silicon carbonitride boron, silicon oxycarbonitride, and a combination thereof, but the present disclosure is not limited thereto.

In some embodiments, the gate dielectric film 120 may include an interfacial film 122 and a high-k film 124 that are sequentially stacked on each of the first through fourth active patterns AP1 through AP4.

The interfacial film 122 may surround the first through third bridge patterns 111 through 113 of each of the first through fourth active patterns AP1 through AP4. For example, the interfacial film 122 may extend conformally along each of the first through third bridge patterns 111 through 113. In some embodiments, the interfacial film 122 may include an oxide film formed by oxidizing the surfaces of the first through third bridge patterns 111 through 113. For example, when the first through third bridge patterns 111 through 113 include Si, the interfacial film 122 may include a silicon oxide film.

The high-k film 124 may surround the interfacial film 122. Additionally, part of the high-k film 124 may be interposed between the gate electrode 130 and the gate spacers 140. For example, the high-k film 124 may extend conformally along the profile of the interfacial film 122 and the inner surfaces of the gate spacer 140. Additionally, the high-k film 124 may further extend along the upper surface of the field insulating film 105.

In some embodiments, the high-k film 124 may include a high-k dielectric material with a dielectric constant that is greater than a dielectric constant of silicon oxide. The high-k dielectric material may include, for example, at least one of hafnium oxide (HfO₂), zirconium oxide (ZrO₂), lanthanum oxide (La₂O₃), aluminum oxide (Al₂O₃), titanium oxide (TiO₂), strontium titanium oxide (SrTiO₃), lanthanum aluminum oxide (LaAlO₃), yttrium oxide (Y₂O₃), hafnium oxynitride (HfOₓN_{y}), zirconium oxynitride (ZrOₓN_{y}), lanthanum oxynitride (La₂OₓN_{y}), aluminum oxynitride (Al₂OₓN_{y}), titanium oxynitride (TiOₓN_{y}), strontium titanium oxynitride (SrTiOₓN_{y}), lanthanum aluminum oxynitride (LaAlOₓN_{y}), yttrium oxynitride (Y₂OₓN_{y}), and a combination thereof, but the present disclosure is not limited thereto.

The gate capping film 150 may extend along the upper surface of the gate electrode 130. The gate capping film 150 may include an insulating material, for example, at least one of silicon oxide, silicon nitride, silicon oxynitride, silicon oxycarbide, silicon nitride boron, silicon carbonitride boron, silicon oxycarbonitride, and a combination thereof, but the present disclosure is not limited thereto.

First through fourth source/drain regions 161 through 164 may be formed in the first through fourth active patterns AP1 through AP4, respectively. The first through fourth source/drain regions 161 through 164 may be components included in the first through fourth active patterns AP1 through AP4, or separate components distinct from the first through fourth active patterns AP1 through AP4.

For example, the first active pattern AP1 may include the first source/drain region 161. The first source/drain region 161 may be formed in the first active pattern AP1 along the side surfaces of the first and third gate structures GS1 and GS3.

For example, the second active pattern AP2 may include the second source/drain region 162. The second source/drain region 162 may be formed in the second active pattern AP2 along the side surfaces of the second and third second gate structures GS2 and GS3.

For example, the third active pattern AP3 may include the third source/drain region 163. The third source/drain region 163 may be formed in the third active pattern AP3 along the side surfaces of the second and third gate structures GS2 and GS3.

For example, the fourth active pattern AP4 may include the fourth source/drain region 164. The fourth source/drain region 164 may be formed in the fourth active pattern AP4 along the side surfaces of the second and fourth gate structures GS2 and GS4.

The first through third bridge patterns 111 through 113 of each of the first through fourth active patterns AP1 through AP4 may penetrate the gate electrode 130 and the gate spacers 140 and may be connected to the corresponding source/drain region. Each of the first through fourth source/drain regions 161 through 164 may be separated from the gate electrode 130 by the gate spacers 140.

In some embodiments, each of the first through fourth source/drain regions 161 through 164 may include an epitaxial layer doped with impurities. For example, each of the first through fourth source/drain regions 161 through 164 may include an epitaxial pattern grown by epitaxial growth from the corresponding active pattern.

When the first and fourth active patterns AP1 and AP4 serve as the channel regions of NFETs, the first and fourth source/drain regions 161 and 164 may include N-type impurities (e.g., P, Sb, or As) or impurities for preventing the diffusion of N-type impurities.

When the second and third active patterns AP2 and AP3 serve as the channel regions of PFETs, the second and third source/drain regions 162 and 163 may include P-type impurities (e.g., B, In, Ga, or Al) or impurities for preventing the diffusion of P-type impurities.

In some embodiments, each of the first through fourth gate structures GS1 through GS4 may further include inner spacers 145. The inner spacers 145 may be formed on the side surfaces of the gate electrode 130 between the first through third bridge patterns 111 through 113. Each of the first through fourth source/drain regions 161 through 164 may be separated from the gate electrode 130 by the gate dielectric film 120, the gate spacers 140, and/or the inner spacers 145. In some embodiments, the inner spacers 145 may be omitted.

The first through sixth source/drain contacts 171 through 176 may be electrically connected to the first through fourth active patterns AP1 through AP4. The shapes and arrangements of the first through sixth source/drain contacts 171 through 176 are merely exemplary and not particularly limited.

The first source/drain contact 171 may be connected to the first active pattern AP1. For example, the first source/drain contact 171 may contact the first source/drain region 161 on one side of the first gate structure GS1. The first gate structure GS1 may be interposed between the first and second source/drain contacts 171 and 172.

The second source/drain contact 172 may connect the first and second active patterns AP1 and AP2. For example, the second source/drain contact 172 may extend in the first direction X and contact both the first and second source/drain regions 161 and 162. The second source/drain contact 172 may be interposed between the first and third gate structures GS1 and GS3, and between the second and third gate structures GS2 and GS3.

The third source/drain contact 173 may be connected to the second active pattern AP2. For example, the third source/drain contact 173 may contact the second source/drain region 162 on one side of the third gate structure GS3. The third gate structure GS3 may be interposed between the second source/drain contacts 172 and 173.

The fourth source/drain contact 174 may be connected to the fourth active pattern AP4. For example, the fourth source/drain contact 174 may contact the fourth source/drain region 164 on one side of the fourth gate structure GS4. The fourth gate structure GS4 may be interposed between the fourth and fifth source/drain contacts 174 and 175.

The fifth source/drain contact 175 may connect the third and fourth active patterns AP3 and AP4. For example, the fifth source/drain contact 175 may extend in the first direction X and contact both the third and fourth source/drain regions 163 and 164. The fifth source/drain contact 175 may be interposed between the second and third gate structures GS2 and GS3, and between the second and fourth gate structures GS2 and GS4.

The sixth source/drain contact 176 may be connected to the third active pattern AP3. For example, the sixth source/drain contact 176 may contact the third source/drain region 163 on one side of the second gate structure GS2. The second gate structure GS2 may be interposed between the fifth and sixth source/drain contacts 175 and 176.

The second source/drain contact 172 may be electrically connected to the second gate structure GS2. For example, a first shared contact 193 may be formed on the second gate structure GS2 and the second source/drain contact 172. The first shared contact 193 may extend in the second direction Y, connecting the gate electrode 130 of the second gate structure GS2 and the second source/drain contact 172. Through the first shared contact 193, the output node of the first inverter INV1 (i.e., the second source/drain contact 172) may be connected to the input node of the second inverter INV2 (i.e., the second gate structure GS2).

The fifth source/drain contact 175 may be electrically connected to the third gate structure GS3. For example, a second shared contact 194 may be formed on the third gate structure GS3 and the fifth source/drain contact 175. The second shared contact 194 may extend in the second direction Y, connecting the gate electrode 130 of the third gate structure GS3 and the fifth source/drain contact 175. Through the second shared contact 194, the output node of the second inverter INV2 (i.e., the fifth source/drain contact 175) may be connected to the input node of the first inverter INV1 (i.e., the third gate structure GS3).

The first interlayer insulating film ID1 may fill the spaces on the side surfaces of the first through fourth gate structures GS1 through GS4. For example, the first interlayer insulating film ID1 may cover the first through fourth source/drain regions 161 through 164. A second interlayer insulating film ID2 may cover the first through fourth gate structures GS1 through GS4 and the first interlayer insulating film ID1.

The first and second interlayer insulating films ID1 and ID2 may each include, for example, at least one of silicon oxide, silicon nitride, silicon oxynitride, silicon oxycarbide, silicon nitride boron, silicon carbonitride, silicon oxycarbonitride, and a low-k dielectric material with a smaller dielectric constant than silicon oxide, but the present disclosure is not limited thereto.

The front region FR may be formed on the first surface 100a of the substrate 100. The front region FR may include a first level front wiring FM1 and a second level front wiring FM2. For example, an interlayer insulating film 200 may be formed on the second interlayer insulating film ID2. The first and second level front wirings FM1 and FM2 may be formed within the interlayer insulating film 200, forming electrical pathways.

The first and second level front wirings FM1 and FM2 may be sequentially stacked on the first surface 100a of the substrate 100. That is, the second level front wiring FM2 may be disposed at a higher level than the first level front wiring FM1. In the front region FR, “higher level” means being disposed further away from the substrate 100 in a vertical direction (hereinafter, a third direction Z). For example, in the third direction Z, the second level front wiring FM2 may be spaced further apart from the first surface 100a than the first level front wiring FM1.

In some embodiments, as illustrated in FIGS. 3 through 7, the first level front wiring FM1 may include first through fifth front wiring patterns 211 through 215 on the memory cell MC. The first through fifth front wiring patterns 211 through 215 may be disposed at the same level. Here, “at the same level” means being disposed at the same height in the third direction Z relative to the substrate 100. The first through fifth front wiring patterns 211 through 215 may be sequentially arranged along the first direction X.

The first front wiring pattern 211 may be connected to the first gate structure GS1. For example, a first gate contact 191, which penetrates the second interlayer insulating film ID2 and the gate capping film 150 to contact the gate electrode 130 of the first gate structure GS1, may be formed. The first front wiring pattern 211 may be connected to the gate electrode 130 of the first gate structure GS1 through the first gate contact 191.

The second front wiring pattern 212 may be connected to the first source/drain contact 171. For example, a first contact via 181, which penetrates the second interlayer insulating film ID2 to contact the first source/drain contact 171, may be formed. The second front wiring pattern 212 may be connected to the first source/drain contact 171 through the first contact via 181. In some embodiments, the second front wiring pattern 212 may extend beyond the memory cell MC in the second direction Y. The second front wiring pattern 212 may serve as a bitline BL and may be connected to the first pass transistor PS1 through the first source/drain contact 171.

The third front wiring pattern 213 may be connected to the third and sixth source/drain contacts 173 and 176. For example, a second contact via 183, which penetrates the second interlayer insulating film ID2 to contact the third source/drain contact 173, may be formed, and a third contact via 186, which penetrates the second interlayer insulating film ID2 to contact the sixth source/drain contact 176, may be formed. The third front wiring pattern 213 may be connected to the third source/drain contact 173 through the second contact via 183 and to the sixth source/drain contact 176 through the third contact via 186. In some embodiments, the third front wiring pattern 213 may extend beyond the memory cell MC in the second direction Y. The third front wiring pattern 213 may serve as a first power supply line applying a first power supply voltage to the first and second pull-up transistors PU1 and PU2.

The fourth front wiring pattern 214 may be connected to the fourth source/drain contact 174. For example, a fourth contact via 184, which penetrates the second interlayer insulating film ID2 to contact the fourth source/drain contact 174, may be formed. The fourth front wiring pattern 214 may be connected to the fourth source/drain contact 174 through the fourth contact via 184. In some embodiments, the fourth front wiring pattern 214 may extend beyond the memory cell MC in the second direction Y. The fourth front wiring pattern 214 may serve as a complementary bitline/BL and may be connected to the second pass transistor PS2 through the fourth source/drain contact 174.

The fifth front wiring pattern 215 may be connected to the fourth gate structure GS4. For example, a second gate contact 192, which penetrates the second interlayer insulating film ID2 and the gate capping film 150 to contact the gate electrode 130 of the fourth gate structure GS4, may be formed. The fifth front wiring pattern 215 may be connected to the gate electrode 130 of the fourth gate structure GS4 through the second gate contact 192.

In some embodiments, as illustrated in FIGS. 8 and 9, the first level front wiring FM1 may further include a sixth front wiring pattern 216 on a transfer cell TC. The sixth front wiring pattern 216 may be disposed at the same level as the first through fifth front wiring patterns 211 through 215.

In some embodiments, as illustrated in FIGS. 3 through 9, the second level front wiring FM2 may include a seventh front wiring pattern 230 on the memory cell MC and the transfer cell TC. The seventh front wiring pattern 230 may extend longitudinally in the first direction X across the memory cell MC and the transfer cell TC.

The seventh front wiring pattern 230 on the memory cell MC may be connected to the first and fifth front wiring patterns 211 and 215. For example, a first front via pattern 221, which connects the first and seventh front wiring patterns 211 and 230, may be formed within the interlayer insulating film 200, and a second front via pattern 222, which connects the fifth and seventh front wiring patterns 215 and 230, may be formed. The seventh front wiring pattern 230 may serve as a wordline WL and may be connected to the gate of the first pass transistor PS1 (i.e., the first gate structure GS1) through the first front wiring pattern 211 and to the gate of the second pass transistor PS2 (i.e., the fourth gate structure GS4) through the fifth front wiring pattern 215.

The seventh front wiring pattern 230 on the transfer cell TC may be connected to the sixth front wiring pattern 216. For example, a third front via pattern 223, which extends in the third direction Z and connects the sixth and seventh front wiring patterns 216 and 230, may be formed.

The back region BR may be formed on the second surface 100b of the substrate 100. The back region BR may include a first level back wiring BM1 and a second level back wiring BM2. For example, a back interlayer insulating film 300 may be formed on the second surface 100b of the substrate 100. The first and second level back wirings BM1 and BM2 may be formed within the back interlayer insulating film 300, forming electrical pathways.

The first and second level back wirings BM1 and BM2 may be sequentially stacked on the second surface 100b of the substrate 100. That is, the second level back wiring BM2 may be disposed at a higher level than the first level back wiring BM1. In the back region BR, “higher level” means being disposed further away from the substrate 100 in the vertical direction (or the third direction Z). For example, in the third direction Z, the second level back wiring BM2 may be spaced further apart from the second surface 100b than the first level back wiring BM1.

In some embodiments, as illustrated in FIGS. 3 through 7, the first level back wiring BM1 may include a first back wiring pattern 310 on the memory cell MC.

The first back wiring pattern 310 may be connected to the first active pattern AP1. For example, a first back source/drain contact 301, which contacts the first source/drain region 161, may be formed on one side of the third gate structure GS3. The first back source/drain contact 301 may penetrate the substrate 100 to connect the first back wiring pattern 310 and the first source/drain region 161. The third gate structure GS3 may be interposed between the second source/drain contact 172 and the first back source/drain contact 301.

The first back wiring pattern 310 may be connected to the fourth active pattern AP4. For example, a second back source/drain contact 302, which contacts the fourth source/drain region 164, may be formed on one side of the second gate structure GS2. The second back source/drain contact 302 may penetrate the substrate 100 to connect the first back wiring pattern 310 and the fourth source/drain region 164. The second gate structure GS2 may be interposed between the fifth source/drain contact 175 and the second back source/drain contact 302.

The first back wiring pattern 310 may serve as a second power supply line applying a second power supply voltage different from the first power supply voltage to the first and second pull-down transistors PD1 and PD2.

In some embodiments, the first back wiring pattern 310 may include a first portion 310a and a second portion 310b, which intersect each other.

The first portion 310a of the first back wiring pattern 310 may extend longitudinally in the first direction X beyond the memory cell MC. The first portion 310a of the first back wiring pattern 310 may overlap with the first back source/drain contact 301 in the third direction Z. That is, the first back source/drain contact 301 may connect the first portion 310a of the first back wiring pattern 310 and the first active pattern AP1.

The second portion 310b of the first back wiring pattern 310 may extend longitudinally in the second direction Y beyond the memory cell MC. The second portion 310b of the first back wiring pattern 310 may overlap with the second back source/drain contact 302 in the third direction Z. That is, the second back source/drain contact 302 may connect the second portion 310b of the first back wiring pattern 310 and the fourth active pattern AP4.

In some embodiments, as illustrated in FIGS. 3 through 9, the second level back wiring BM2 may include a second back wiring pattern 330 on the memory cell MC and the transfer cell TC. The second back wiring pattern 330 may extend longitudinally in the first direction X across the memory cell MC and the transfer cell TC.

The transfer cell TC may connect the seventh front wiring pattern 230 and the second back wiring pattern 330. Specifically, the transfer cell TC may include a through via 315. The through via 315 may extend in the third direction Z and penetrate the substrate 100 within the transfer cell TC. The through via 315 may electrically connect the seventh front wiring pattern 230 and the second back wiring pattern 330. For example, a front contact pattern 177, which penetrates the first interlayer insulating film ID1 and contacts the through via 315, may be formed, and a fifth contact via 187, which penetrates the second interlayer insulating film ID2 and connects the front contact pattern 177 and the sixth front wiring pattern 216, may be formed. Additionally, for example, a back via pattern 320, which connects the second back wiring pattern 330 and the through via 315 within the back interlayer insulating film 300, may be formed.

As the seventh front wiring pattern 230, which is provided as a wordline WL, is connected to the second back wiring pattern 330, the second back wiring pattern 330 may also be provided as the wordline WL. That is, the wordline WL may include the seventh front wiring pattern 230, which extends in the first direction X on the first surface 100a of the substrate 100, and the second back wiring pattern 330, which extends in the first direction X on the second surface 100b of the substrate 100.

In some embodiments, the width of the through via 315 may decrease from the back region BR toward the front region FR (e.g., in the third direction Z). This may be due to the etching process for forming the through via 315 being performed from the second surface 100b of the substrate 100 toward the first surface 100a of the substrate 100.

In some embodiments, the through via 315 may protrude beyond the field insulating film 105 toward the first interlayer insulating film ID1. For example, the upper surface of the through via 315 may be formed higher than the upper surface of the field insulating film 105.

In some embodiments, the through via 315 may protrude beyond the substrate 100 toward the back interlayer insulating film 300. For example, the lower surface of the through via 315 may be formed lower than the second surface 100b of the substrate 100.

In some embodiments, the front contact pattern 177 may be formed at the same level as the first through sixth source/drain contacts 171 through 176. In some embodiments, the fifth contact via 187 may be formed at the same level as the first, second, third, and fourth contact vias 181, 183, 186, and 184. Here, “at the same level” means being formed by the same manufacturing process.

In some embodiments, a first insulating structure IS1 and a second insulating structure IS2 may be formed on the first surface 100a of the transfer cell TC. The first and second insulating structures IS1 and IS2 may be formed on the substrate 100 and the field insulating film 105. The first and second insulating structures IS1 and IS2 may be spaced apart from each other in the second direction Y and may extend longitudinally in the first direction X. The first insulating structure IS1 may be arranged along the first direction X with the first and second gate structures GS1 and GS2. The second insulating structure IS2 may be arranged along the first direction X with the third and fourth gate structures GS3 and GS4.

In some embodiments, the through via 315 may be interposed between the first and second insulating structures IS1 and IS2. In some embodiments, part of the through via 315 may overlap with the first insulating structure IS1 and/or the second insulating structure IS2 in the third direction Z.

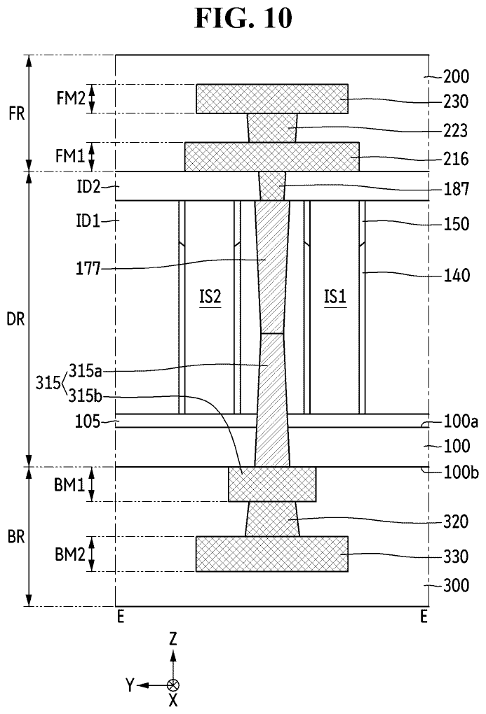

FIG. 10 is a schematic cross-sectional view for explaining a unit transfer cell of a semiconductor device according to some embodiments. For convenience, features that overlap with those described above with reference to FIGS. 1 through 9 will be briefly explained or omitted.

Referring to FIG. 10, in the semiconductor device according to some embodiments, a through via 315 includes a back contact pattern 315a and a third back wiring pattern 315b.

The back contact pattern 315a may penetrate a substrate 100 and a field insulating film 105 to connect a front contact pattern 177 and the third back wiring pattern 315b. The third back wiring pattern 315b may connect the back contact pattern 315a and a back via pattern 320 within a back interlayer insulating film 300.

In some embodiments, the third back wiring pattern 315b may be disposed at the same level as a first back wiring pattern 310. That is, a first level back wiring BM1 may further include the third back wiring pattern 315b.

In some embodiments, the back contact pattern 315a may protrude beyond the field insulating film 105 toward a first interlayer insulating film ID1. For example, the upper surface of the back contact pattern 315a may be formed higher than the upper surface of the field insulating film 105.

In some embodiments, the lower surface of the back contact pattern 315a may be disposed coplanar with a second surface 100b of the substrate 100.

In some embodiments, the back contact pattern 315a may be formed at the same level as first and second back source/drain contacts 301 and 302.

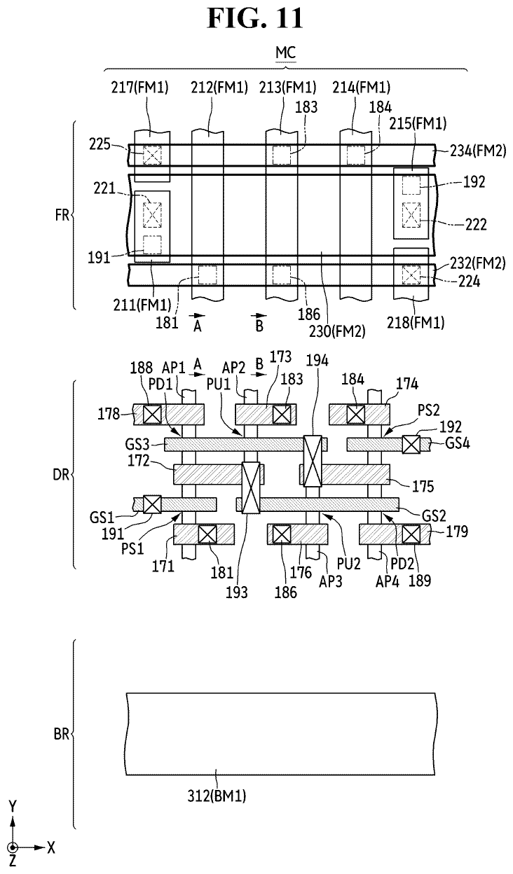

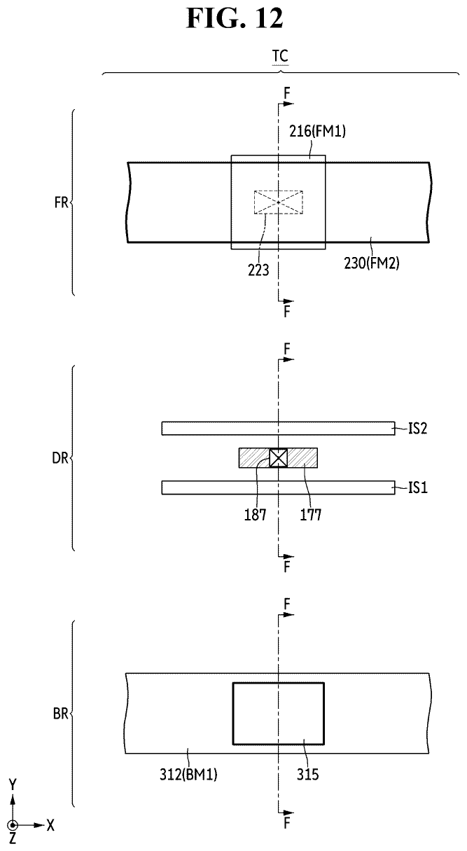

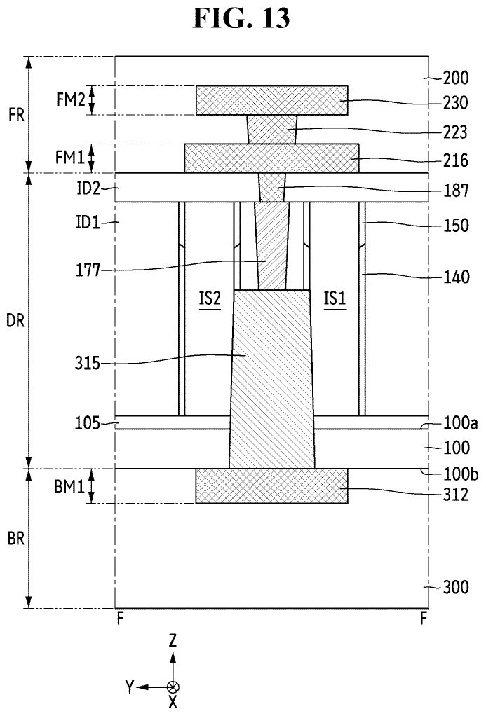

FIG. 11 is a layout view for explaining a unit memory cell of a semiconductor device according to some embodiments. FIG. 12 is a schematic cross-sectional view for explaining a unit transfer cell of a semiconductor device according to some embodiments. FIG. 13 is a schematic cross-sectional view taken along line F-F of FIG. 12. For convenience, features that overlap with those described above with reference to FIGS. 1 through 9 will be briefly explained or omitted.

Referring to FIGS. 11 through 13, in the semiconductor device according to some embodiments, a first level front wiring FM1 further includes an eighth front wiring pattern 217 and a ninth front wiring pattern 218, a second level front wiring FM2 further includes a tenth front wiring pattern 232 and an eleventh front wiring pattern 234, and a first level back wiring BM1 includes a fourth back wiring pattern 312 on a memory cell MC and a transfer cell TC.

The eighth front wiring pattern 217 may be connected to a first active pattern AP1. For example, a seventh source/drain contact 178, which contacts a first source/drain region 161, may be formed on one side of a third gate structure GS3. The third gate structure GS3 may be interposed between a second source/drain contact 172 and the seventh source/drain contact 178. The eighth front wiring pattern 217 may be connected to the seventh source/drain contact 178. For example, a sixth contact via 188, which penetrates a second interlayer insulating film ID2 to contact the seventh source/drain contact 178, may be formed. The eighth front wiring pattern 217 may be connected to the seventh source/drain contact 178 through the sixth contact via 188. In some embodiments, the eighth front wiring pattern 217 may be arranged along a second direction Y with a first front wiring pattern 211.

The ninth front wiring pattern 218 may be connected to a fourth active pattern AP4. For example, an eighth source/drain contact 179, which contacts a fourth source/drain region 164, may be formed on one side of a second gate structure GS2. The second gate structure GS2 may be interposed between a fifth source/drain contact 175 and the eighth source/drain contact 179. The ninth front wiring pattern 218 may be connected to the eighth source/drain contact 179. For example, a seventh contact via 189, which penetrates the second interlayer insulating film ID2 to contact the eighth source/drain contact 179, may be formed. The ninth front wiring pattern 218 may be connected to the eighth source/drain contact 179 through the seventh contact via 189. In some embodiments, the ninth front wiring pattern 218 may be arranged along the second direction Y with a fifth front wiring pattern 215.

The tenth front wiring pattern 232 may extend longitudinally in a first direction X. The tenth front wiring pattern 232 may be connected to the ninth front wiring pattern 218. For example, a fourth front via pattern 224, which connects the ninth front wiring pattern 218 and the tenth front wiring pattern 232 within a front interlayer insulating film 200, may be formed. The tenth front wiring pattern 232 may serve as a second power supply line applying a second power supply voltage to a second pull-down transistor PD2.

The eleventh front wiring pattern 234 may extend longitudinally in the first direction X. The eleventh front wiring pattern 234 may be connected to the eighth front wiring pattern 217. For example, a fifth front via pattern 225, which connects the eighth front wiring pattern 217 and the eleventh front wiring pattern 234 within the front interlayer insulating film 200, may be formed. The eleventh front wiring pattern 234 may serve as a second power supply line applying the second power supply voltage to a first pull-down transistor PD1.

The fourth back wiring pattern 312 may extend longitudinally in the first direction X across the memory cell MC and the transfer cell TC. The transfer cell TC may connect the seventh front wiring pattern 230 and the fourth back wiring pattern 312. Specifically, a through via 315 may electrically connect the seventh front wiring pattern 230 and the fourth back wiring pattern 312. For example, the fourth back wiring pattern 312 may contact the lower surface of the through via 315.

As the seventh front wiring pattern 230, which is provided as a wordline WL, is connected to the fourth back wiring pattern 312, the fourth back wiring pattern 312 may also be provided as the wordline WL. That is, the wordline WL may include the seventh front wiring pattern 230, which extends in the first direction X on a first surface 100a of a substrate 100, and the fourth back wiring pattern 312, which extends in the first direction X on a second surface 100b of the substrate 100.

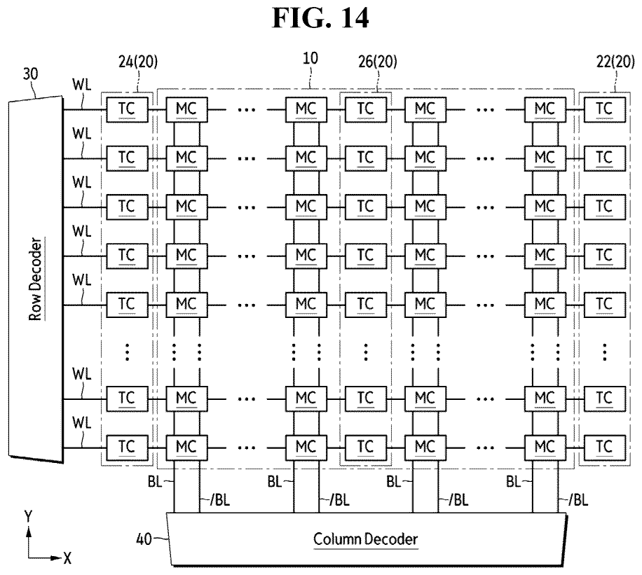

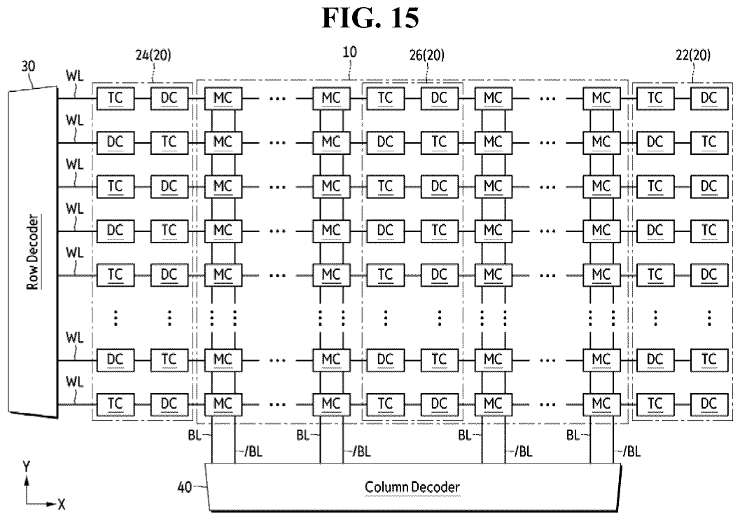

FIGS. 14 and 15 are block diagrams for explaining semiconductor devices according to some embodiments. For convenience, features that overlap with those described above with reference to FIGS. 1 through 13 will be briefly explained or omitted.

Referring to FIGS. 14 and 15, in the semiconductor devices according to some embodiments, a transfer cell region 20 further includes a third transfer cell region 26.

The third transfer cell region 26 may be disposed within a cell array region 10. For example, the third transfer cell region 26 may be interposed between some of a plurality of memory cells MC and a row decoder 30, and other memory cells MC may be interposed between the row decoder 30 and the third transfer cell region 26. In some embodiments, some of the memory cells MC may be interposed between a first transfer cell region 22 and the third transfer cell region 26. In some embodiments, other memory cells MC may be interposed between a second transfer cell region 24 and the third transfer cell region 26. The third transfer cell region 26 may include a plurality of transfer cells TC, which are arranged along a second direction Y.

In FIGS. 14 and 15, the third transfer cell region 26 is illustrated as being disposed at the center of the cell array region 10, but the present disclosure is limited thereto. Alternatively, the third transfer cell region 26 may be more adjacent to the first transfer cell region 22 or to the second transfer cell region 24.

Additionally, in FIGS. 14 and 15, only one third transfer cell region 26 is illustrated as being disposed within the cell array region 10, but the present disclosure is not limited thereto. Alternatively, a plurality of third transfer cell regions 26 arranged along a first direction X may be disposed within the cell array region 10. The plurality of third transfer cell regions 26 may be spaced apart from one another in the first direction X or may be adjacent to one another in the first direction X.

Referring to FIG. 15, a plurality of transfer cells TC are arranged in a zigzag pattern in a transfer cell region 20.

For example, in each of first, second, and third transfer cell regions 22, 24, and 26, the transfer cells TC may be arranged in a staggered manner in first and second directions X and Y. In some embodiments, the transfer cell region 20 may further include a plurality of dummy cells DC. The dummy cells DC may be alternately arranged with the transfer cells TC in the second direction Y.

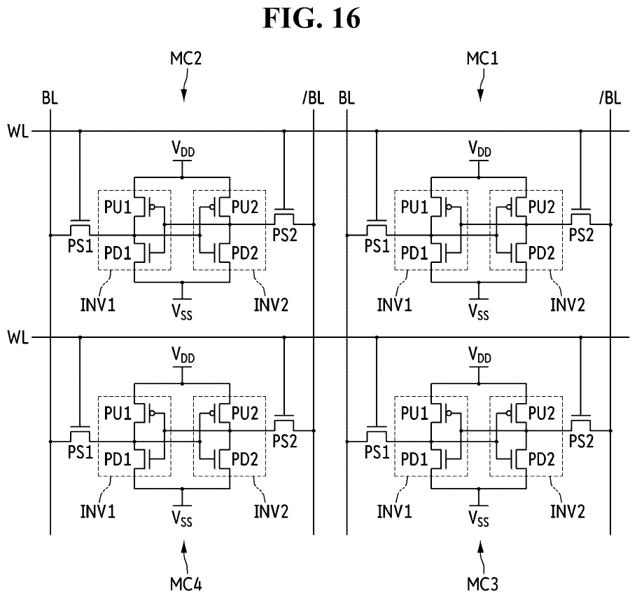

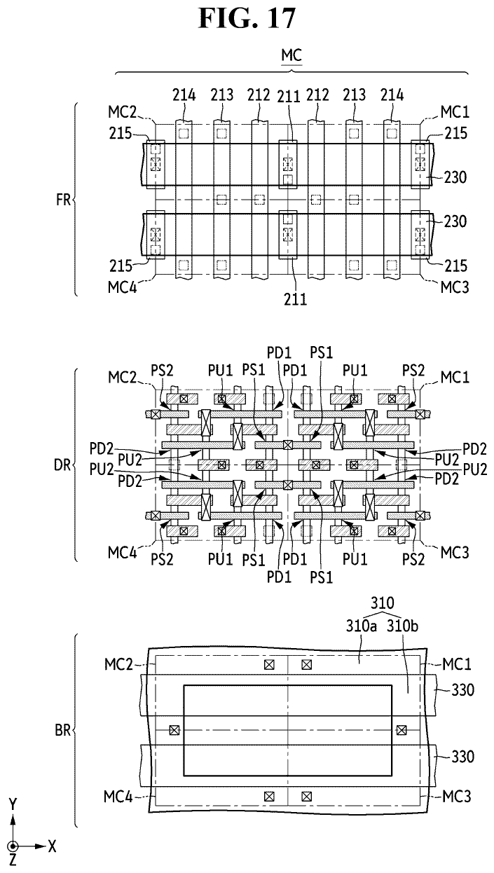

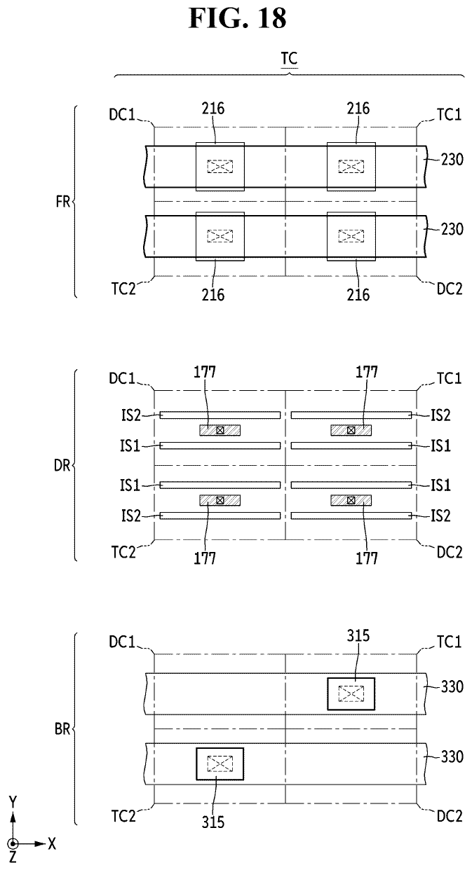

FIG. 16 is a circuit diagram for explaining a semiconductor device according to some embodiments. FIGS. 17 and 18 are exemplary layout views for explaining the semiconductor device of FIG. 16.

Referring to FIG. 16, the semiconductor device according to some embodiments includes first through fourth memory cells MC1 through MC4, which are adjacent to one another.

Each of the first through fourth memory cells MC1 through MC4 may include a pair of first and second inverters INV1 and INV2, which are connected in parallel between a power supply node V_{DD} and a ground node V_{SS}, and first and second pass transistors PS1 and PS2, which are connected to the output nodes of the first and second inverters INV1 and INV2, respectively. The first through fourth memory cells MC1 through MC4 are the same as described above with reference to FIG. 2, and thus, detailed descriptions thereof will be omitted.

In some embodiments, the first and second memory cells MC1 and MC2 may share a wordline WL, and the third and fourth memory cells MC3 and MC4 may share another wordline WL. For example, the gates of the first and second pass transistors PS1 and PS2 of the first memory cell MC1 and the gates of the first and second pass transistors PS1 and PS2 of the second memory cell MC2 may be commonly connected to one wordline WL. Additionally, the gates of the first and second pass transistors PS1 and PS2 of the third memory cell MC3 and the gates of the first and second pass transistors PS1 and PS2 of the fourth memory cell MC4 may be commonly connected to another wordline WL.

In some embodiments, the first and third memory cells MC1 and MC3 may share a bitline BL and a complementary bitline/BL, and the second and fourth memory cells MC2 and MC4 may share another bitline BL and another complementary bitline/BL. For example, the first pass transistors PS1 of the first and third memory cells MC1 and MC3 may be commonly connected to one bitline BL, and the second pass transistors PS2 of the first and third memory cells MC1 and MC3 may be commonly connected to one complementary bitline/BL. Additionally, the first pass transistors PS1 of the second and fourth memory cells MC2 and MC4 may be commonly connected to another bitline BL, and the second pass transistors PS2 of the second and fourth memory cells MC2 and MC4 may be commonly connected to another complementary bitline/BL.

Referring to FIGS. 16 through 18, the semiconductor device according to some embodiments includes the first through fourth memory cells MC1 through MC4, a first transfer cell TC1, and a second transfer cell TC2.

The first through fourth memory cells MC1 through MC4 in FIG. 17 are the same as described above with reference to FIGS. 3 through 7, and thus detailed descriptions thereof will be omitted. Additionally, the first and second transfer cells TC1 and TC2 in FIG. 18 are the same as described above with reference to FIGS. 8 and 9, and thus, detailed descriptions thereof will be omitted.

The first and second memory cells MC1 and MC2 may be arranged in planar symmetry with respect to a plane (i.e., a YZ plane) that intersects a first direction X. The third and fourth memory cells MC3 and MC4 may be arranged in planar symmetry with respect to the plane (i.e., the YZ plane) that intersects the first direction X. The first and third memory cells MC1 and MC3 may be arranged in planar symmetry with respect to a plane (i.e., an XZ plane) that intersects a second direction Y. The second and fourth memory cells MC2 and MC4 may be arranged in planar symmetry with respect to the plane (i.e., the XZ plane) that intersects the second direction Y.

Second front wiring patterns 212 and fourth front wiring patterns 214 may be repeatedly arranged in the first direction X. One second front wiring pattern 212 may extend in the second direction Y and may be provided as a bitline BL commonly connected to the first and third memory cells MC1 and MC3. Another second front wiring pattern 212 may extend in the second direction Y and may be provided as another bitline BL commonly connected to the second and fourth memory cells MC2 and MC4. One fourth front wiring pattern 214 may extend in the second direction Y and may be provided as a complementary bitline/BL commonly connected to the first and third memory cells MC1 and MC3. Another fourth front wiring pattern 214 may extend in the second direction Y and may be provided as another complementary bitline/BL commonly connected to the second and fourth memory cells MC2 and MC4.

Third front wiring patterns 213 may be repeatedly arranged in the first direction X. One third front wiring pattern 213 may extend in the second direction Y and may be provided as a first power supply line applying a first power supply voltage to the first and third memory cells MC1 and MC3. Another third front wiring pattern 213 may extend in the second direction Y and may be provided as a first power supply line applying the first power supply voltage to the second and fourth memory cells MC2 and MC4.

Seventh front wiring patterns 230 may be repeatedly arranged in the second direction Y.

One seventh front wiring pattern 230 may extend in the first direction X and may be provided as a wordline WL commonly connected to the first and second memory cells MC1 and MC2. For example, this one seventh front wiring pattern 230 may be shared by the first and second memory cells MC1 and MC2 through a first front wiring pattern 211 and fifth front wiring patterns 215. In some embodiments, the first and second memory cells MC1 and MC2 may share this one first front wiring pattern 211.

Another seventh front wiring pattern 230 may extend in the first direction X and may be provided as a wordline WL commonly connected to the third and fourth memory cells MC3 and MC4. For example, this other seventh front wiring pattern 230 may be shared by the third and fourth memory cells MC3 and MC4 through a first front wiring pattern 211 and fifth front wiring patterns 215. In some embodiments, the third and fourth memory cells MC3 and MC4 may share this other first front wiring pattern 211.

A first back wiring pattern 310 may be provided as a second power supply line applying a second power supply voltage to the first through fourth memory cells MC1 through MC4. In some embodiments, the first back wiring pattern 310 may be commonly connected to the first through fourth memory cells MC1 through MC4. For example, as illustrated in FIG. 17, the first back wiring pattern 310, which includes a first portion 310a and a second portion 310b, may form a closed loop that extends continuously across the first through fourth memory cells MC1 through MC4. The first back wiring pattern 310 may provide a mesh wiring pattern across the entire cell array region 10.

Second back wiring patterns 330 may be repeatedly arranged in the second direction Y.

One second back wiring pattern 330 may be connected to one seventh front wiring pattern 230. For example, the first transfer cell TC1 may include a through via 315 that electrically connects the seventh front wiring pattern 230 and the second back wiring pattern 330. Thus, the second back wiring pattern 330 may be provided as a wordline WL on the backside of the substrate 100.

Another second back wiring pattern 330 may be connected to another seventh front wiring pattern 230. For example, the second transfer cell TC2 may include a through via 315 that electrically connects the seventh front wiring pattern 230 and the second back wiring pattern 330. Thus, the second back wiring pattern 330 may be provided as a wordline WL on the backside of the substrate 100.

In some embodiments, the first and second transfer cells TC1 and TC2 may be arranged diagonally between the first and second directions X and Y. For example, as illustrated in FIG. 18, the first and second dummy cells DC1 and DC2 may be further formed. The first dummy cell DC1 may be arranged along the first direction X with the first transfer cell TC1 and along the second direction Y with the second transfer cell TC2. The second dummy cell DC2 may be arranged along the second direction Y with the first transfer cell TC1 and along the first direction X with the second transfer cell TC2.

As semiconductor devices become increasingly integrated, individual circuit patterns are being miniaturized to implement more semiconductor devices in the same area. Consequently, there is a problem of signal delays in the transmission of electrical signals through wiring. For example, due to the characteristics of each unit memory cell, an SRAM may be formed longer in the direction (e.g., the second direction Y) where wordlines extend than in the direction (e.g., the first direction X) where bitlines extend. As a result, wordline signal delays increase in relatively distant unit memory cells.

Conversely, the semiconductor devices according to some embodiments can mitigate these electrical signal delays using a Backside Power Delivery Network (BSPDN). Specifically, the semiconductor devices according to some embodiments include a transfer cell region 20 in which a plurality of transfer cells TC are arranged. As described above, each transfer cell TC may connect a seventh front wiring pattern 230 provided as a wordline WL on the front side of a substrate 100 and a second back wiring pattern 330 on the backside of the substrate 100. Thus, wordlines WL may also be provided on the backside of the substrate 100, where wiring density is lower than on the front side of the substrate 100. Additionally, as described above, the transfer cell region 20 may be disposed on at least one side of a cell array region 10 in the first direction X and/or within the cell array region 10. Therefore, the wordlines WL can deliver electrical signals to memory cells MC regardless of the distance from a row decoder 30. This can reduce electrical signal delays, thereby providing a semiconductor device with enhanced performance.

While aspects of embodiments have been particularly shown and described, it will be understood that various changes in form and details may be made therein without departing from the spirit and scope of the following claims.

What is claimed is:

1. A semiconductor device comprising:
a substrate having first and second surfaces that are opposite to each other;
a wordline comprising a front wiring pattern on the first surface, extending in a first direction, and a back wiring pattern on the second surface, extending in the first direction;
a bitline and a complementary bitline on the substrate, extending in parallel to each other in a second direction intersecting the first direction; and
first and second cells on the substrate, arranged along the first direction,
wherein the first cell comprises:
a latch circuit comprising a first inverter and a second inverter;
a first pass transistor connected between an output node of the first inverter and the bitline; and
a second pass transistor connected between an output node of the second inverter and the complementary bitline,
wherein the wordline is connected to a gate of the first pass transistor and a gate of the second pass transistor, and
wherein the second cell comprises a through via penetrating the substrate and connecting the front wiring pattern and the back wiring pattern.

2. The semiconductor device of claim 1, wherein the bitline and the complementary bitline are each on the first surface.

3. The semiconductor device of claim 2, wherein the front wiring pattern is farther from the substrate than each of the bitline and the complementary bitline.

4. The semiconductor device of claim 1, further comprising a first power supply line and a second power supply line on the substrate,
wherein the first power supply line and the second power supply line provide different voltages, and
wherein the first inverter and the second inverter are connected in parallel between the first power supply line and the second power supply line.

5. The semiconductor device of claim 4, wherein the first power supply line is on the first surface, and
wherein the second power supply line is on the second surface.

6. The semiconductor device of claim 5, wherein the second power supply line comprises a first portion extending in the first direction and a second portion extending in the second direction.

7. The semiconductor device of claim 5, wherein the bitline, the complementary bitline and the first power supply line are provided at a common level.

8. The semiconductor device of claim 5, wherein the front wiring pattern is farther from the substrate than the first power supply line.

9. The semiconductor device of claim 5, wherein the back wiring pattern is farther from the substrate than the second power supply line.

10. The semiconductor device of claim 4, wherein the first power supply line and the second power supply line are each on the first surface.

11. A semiconductor device comprising:
a substrate having first and second surfaces that are opposite to each other;
a cell array region on the substrate, the cell array region comprising a plurality of memory cells arranged in a matrix form along a first direction and a second direction that intersects the first direction;
a wordline commonly connected to a row of memory cells extending in the first direction, among the plurality of memory cells;
a bitline commonly connected to a column of memory cells extending in the second direction, among the plurality of memory cells; and
a transfer cell region extending in the first direction,
wherein the wordline comprises a front wiring pattern on the first surface, extending in the first direction, and a back wiring pattern on the second surface, extending in the first direction, and
wherein the transfer cell region comprises a through via penetrating the substrate to connect the front wiring pattern and the back wiring pattern.

12. The semiconductor device of claim 11, further comprising a complementary bitline commonly connected to the column of memory cells,
wherein each of the plurality of memory cells comprises:
a latch circuit comprising a first inverter and a second inverter;
a first pass transistor connected between an output node of the first inverter and the bitline; and
a second pass transistor connected between an output node of the second inverter and the complementary bitline, and
wherein the wordline is connected to a gate of the first pass transistor and a gate of the second pass transistor.

13. The semiconductor device of claim 11, further comprising a row decoder connected to the cell array region through the wordline,
wherein at least some of the plurality of memory cells are between the transfer cell region and the row decoder.

14. The semiconductor device of claim 13, wherein the transfer cell region is between some of the plurality of memory cells and the row decoder.

15. The semiconductor device of claim 11, wherein the transfer cell region is provided on both sides of the cell array region in the first direction.

16. A semiconductor device comprising:
a first cell and a second cell arranged along a first direction;
a substrate having a first and second surface that are opposite to each other;
first through fourth active patterns on the first surface of the substrate, sequentially arranged along the first direction and extending in a second direction intersecting the first direction;
a first gate structure extending in the first direction and intersecting the first active pattern;
a second gate structure extending in the first direction and intersecting the third active pattern and the fourth active pattern;
a third gate structure extending in the first direction and intersecting the first active pattern and the second active pattern;
a fourth gate structure extending in the first direction and intersecting the fourth active pattern;
a first source/drain contact connecting the first active pattern and the second active pattern, the first source/drain contact extending between the first gate structure and the third gate structure, and between the second gate structure and the third gate structure;
a second source/drain contact connecting the third active pattern and the fourth active pattern, the second source/drain contact extending between the second gate structure and the fourth gate structure, and between the second gate structure and the third gate structure;
a first shared contact connecting the second gate structure and the first source/drain contact;
a second shared contact connecting the third gate structure and the second source/drain contact;
a first front wiring pattern on the first surface, extending in the first direction and connected to the first gate structure and the fourth gate structure;
a first back wiring pattern on the second surface, extending in the first direction; and
a through via in the second cell, penetrating the substrate and connecting the first front wiring pattern and the first back wiring pattern.

17. The semiconductor device of claim 16, wherein the first back wiring pattern extends in the first direction across the first cell and the second cell.

18. The semiconductor device of claim 16, further comprising:
a third source/drain contact connected to the first active pattern, wherein the first gate structure is between the first source/drain contact and the third source/drain contact;
a fourth source/drain contact connected to the fourth active pattern, wherein the fourth gate structure is between the second source/drain contact and the fourth source/drain contact;
a second front wiring pattern on the first surface, extending in the second direction and connected to the third source/drain contact; and
a third front wiring pattern on the first surface, extending in the second direction and connected to the fourth source/drain contact.

19. The semiconductor device of claim 16, further comprising:
a third source/drain contact connected to the second active pattern, wherein the third gate structure is between the first source/drain contact and the third source/drain contact;
a fourth source/drain contact connected to the third active pattern, wherein the second gate structure is between the second source/drain contact and the fourth source/drain contact; and
a second front wiring pattern on the first surface, extending in the second direction and connected to the third source/drain contact and the fourth source/drain contact.

20. The semiconductor device of claim 16, further comprising:
a first back source/drain contact connected to the first active pattern, wherein the third gate structure is between the first source/drain contact and the first back source/drain contact;
a second back source/drain contact connected to the fourth active pattern, wherein the second gate structure is between the second source/drain contact and the second back source/drain contact; and
a second back wiring pattern on the second surface, wherein the second back wiring pattern is connected to the first back source/drain contact and the second back source/drain contact,
wherein the second back wiring pattern comprises a first portion extending in the first direction and overlapping the first back source/drain contact, and a second portion extending in the second direction and overlapping the second back source/drain contact.
